(19) United States
(12) Patent Application Publication
(10) Pub. No.: US 2026/0209590 A1
(43) Pub. Date: Jul. 23, 2026

(54) PHASE CHANGE THERMAL INTERFACE MATERIAL WITH HIGH THERMAL CONDUCTION COEFFICIENT AND PUMP-OUT RESISTANCE

(71) Applicant: Solstice Advanced Materials US, Inc., Morris Plains, NJ (US)

(72) Inventors: Kai Wang, Shanghai (CN); Hongjiang Chen, Zhangjiagang (CN); Lu Xiao, Zhangjiagang (CN); Shiming He, Zhangjiagang (CN)

(21) Appl. No.: 19/453,800

(22) Filed: Jan. 20, 2026

Related U.S. Application Data
(60) Provisional application No. 63/748,265, filed on Jan. 22, 2025.

(51) Int. Cl. C09K 5/14; C08K 3/013; C08K 3/08; C08L 23/00; C09K 5/06; H05K 7/20

(52) U.S. Cl. CPC C09K 5/14; C08K 3/013; C08K 3/08; C08L 23/00; C09K 5/063; H05K 7/2039; C08K 2003/0812; C08K 2201/005; C08K 2201/011; C08L 2201/08; C08L 2203/20; C08L 2205/06

(57) ABSTRACT

The present disclosure provides a phase change thermal interface material (PC TIM) including a polymeric matrix material, a first thermally conductive filler, a second thermally conductive material, a third thermally conductive material, and a fourth thermally conductive material. The first thermally conductive material has an average particle size between 12-30 μm. The second thermally conductive material has an average particle size between 3-12 μm. The third thermally conductive material has an average particle size between 1-2 μm. The fourth thermally conductive material has an average particle size between 0.03-1.0 μm. The PC TIM has a thermal conductivity coefficient between 8.1 and 12.09 W/m·K. Optionally, the PC TIM may comprise a fifth thermally conductive filler. The fifth thermally conductive material has an average particle size between 0.03-1.0 μm.

### CROSS REFERENCE

This application claims the benefit under 35 U.S.C. § 119(e) of U.S. Provisional Application No. 63/748,265 entitled “PHASE CHANGE THERMAL INTERFACE MATERIAL WITH HIGH THERMAL CONDUCTION COEFFICIENT AND PUMP-OUT RESISTANCE, filed on Jan. 22, 2025, the entire disclosure of which is incorporated by reference in its entirety.

### FIELD

The present disclosure generally relates to thermal interface materials, and more particularly, to phase change-type thermal interface materials.

### BACKGROUND

Thermal interface materials (TIMs) are widely used to dissipate heat from electronic components, such as central processing units, video graphics arrays, servers, game consoles, smart phones, LED boards, and the like. Thermal interface materials are typically used to transfer excess heat from the electronic component to a heat spreader, such as a heat sink.

A practice in the industry becoming more common is to use TIMs that include, among other materials, thermal greases, liquid metals (LM) and/or gap fillers. Compared to conventional TIMs (e.g., thermal greases, LMs, gap fillers) phase change (PC) TIMs offer several advantages owing to their intrinsically high wettability. However, the thermal conductivity (K) of traditional PC TIMs is relatively low, around 8 W/m·K. The low thermal conductivity limits the overall heat transfer capabilities of existing PC TIMs. As such, there is a need for PC-based TIM compositions that do not exhibit such drawbacks.

### SUMMARY

The present disclosure provides a phase change thermal interface material (PC TIM). The PC TIM includes a polymeric matrix material; a first thermally conductive filler with an average particle size between about 12-30 μm; a second thermally conductive filler with an average particle size between about 3-12 μm; a third thermally conductive filler with an average particle size between about 1-2 μm; and a fourth thermally conductive filler with an average particle size between about 0.03-1.0 μm. The polymeric matrix material has a thermal conductivity coefficient between 8.1 and 12.09 W/m·K as determined by ASTM D5470.

The present disclosure further provides an electronic component. The electronic component includes: a heat sink; an electronic chip; and a thermal interface material positioned between the heat sink and the electronic chip. The thermal interface material includes a polymeric matrix material; a first thermally conductive filler with an average particle size between about 12-30 μm; a second thermally conductive filler with an average particle size between about 3-12 μm; a third thermally conductive filler with an average particle size between about 1-2 μm; and a fourth thermally conductive filler with an average particle size between about 0.1-1.0 μm. The polymeric matrix material has a thermal conductivity coefficient between 8.1 and 12.09 W/m·K as determined by ASTM D5470.

### BRIEF DESCRIPTION OF THE DRAWINGS

The above-mentioned and other features and advantages of this disclosure, and the manner of attaining them, will become more apparent and the invention itself will be better understood by reference to the following description of embodiments of the invention taken in conjunction with the accompanying drawings, wherein:

FIG. 1 is an illustration of an electrical component and a heat sink with the PC TIM of the present disclosure within a gap between the electrical component and heat sink and a graph of the temperature v. distance of the illustrated PC TIM;

FIG. 2 is an illustration of the thermally conductive filler with varying particle sizes in the PC TIM of the present disclosure;

FIG. 3A is a graph of the thickness v. thermal resistance of Inventive PC TIM No. 1;

FIG. 3B is a graph of the thickness v. thermal resistance of Inventive PC TIM No. 2;

FIG. 3C is a graph of the thickness v. thermal resistance of Inventive PC TIM No. 3;

FIG. 3D is a graph of the thickness v. thermal resistance of Inventive PC TIM No. 4;

FIG. 3E is a graph of the thickness v. thermal resistance of Comparative TIM No. 1;

FIG. 3F is a graph of the thickness v. thermal resistance of Comparative TIM No. 2;

FIG. 3G is a graph of the thickness v. thermal resistance of Inventive PC TIM No. 5;

FIG. 3H is a graph of the thickness v. thermal resistance of Comparative PC TIM No. 3;

FIG. 4 is a graph of temperature v. complex module of Inventive PC TIMs 1-4 and Comparative TIMs 1-2;

FIG. 5 is a graph of temperature v. tan δ of Inventive PC TIMs 1-4 and Comparative TIMs 1-2;

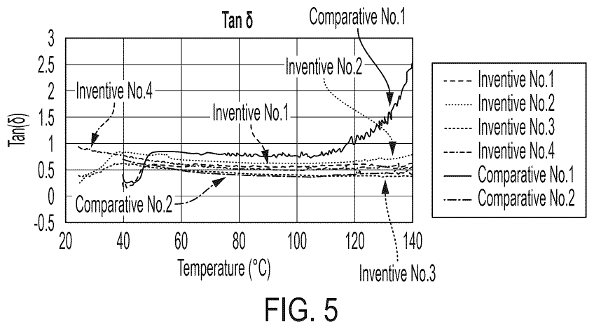

FIG. 6A is a graph of the thermal impedance v. time of Comparative PC TIM 3; and

FIG. 6B is a graph of thermal impedance v. time of Inventive PC TIM 5.

Corresponding reference characters indicate corresponding parts throughout the several views. The exemplifications set out herein illustrate exemplary embodiments of the invention and such exemplifications are not to be construed as limiting the scope of the invention in any manner.

### DETAILED DESCRIPTION

The present invention relates to thermal interface materials (TIMs) useful in transferring heat away from electronic components, which resolve the issues associated with traditional Phase Change (PC) TIMs. The PC TIM may include a polymeric matrix material, and at least four thermally conductive fillers, each comprising different particle size diameters that are less than one another (e.g., the first being larger than the second, second being larger than the third, the third being larger than the fourth, etc.). The combination of the at least four fillers and the polymeric matrix material results in a higher thermal conductivity coefficient (K TIM) than traditional PC TIMS, thus reducing the overall bulk resistance (R Bulk) of the thermal interface material, and increasing the performance of the PC-type TIM. The present PC TIM also exhibits beneficial flowability characteristics, including high resistance to pump out (e.g., a low complex modulus and high Tan). Therefore, the present PC TIM not only has higher thermal performance, but also exhibits higher reliability than traditional PC TIMs.

### I. Phase Change-Type Thermal Interface Material:

A Phase Change (PC)-type Thermal Interface Material (TIM) is a substance used to improve thermal contact between surfaces, such as a heat spreader and a heat sink. PC TIMs soften and/or liquefy at operating temperatures, filling in microscopic gaps to enhance heat transfer away from the heat sink while maintaining electrical insulation.

Here, phase change thermal interface materials (PC TIMs) exhibit lower thermal resistance compared with conventional thermal gels and/or greases, making it a suitable choice for heat dissipation of electronic devices.

The total thermal resistance of TIMs is determined by the contact resistance as well as bulk resistance. Contact Resistance refers to the resistance to heat flow at the interfaces between the TIM and the surfaces it connects (e.g., between a CPU and a heat sink). Contact resistance arises due to surface roughness and imperfections that prevent full contact. Bulk resistance is the resistance to heat flow within the TIM itself, determined by its thickness and thermal conductivity. The total resistance of a TIM is the sum of both contact and bulk resistances, affecting the overall efficiency of heat transfer/heat flux (e.g., the total thermal resistance of the material).

Thermal conductivity is inversely proportional to the thermal resistance of the TIM (e.g., the lower the total thermal resistance, the higher the thermal conductivity). Here, it has been found that the thermal conductivity of the PC-type TIMs is relatively high.

Specifically, the wettability of Phase Change type TIMs is high, as compared to other types of TIMs including thermal grease/pastes, pads, adhesives, tapes, liquid metals (LMs) and the like. Wettability refers to the TIM material's ability to spread and conform to the surfaces it contacts. High wettability ensures that the TIM material fills microscopic gaps and irregularities between the surfaces, improving thermal contact and reducing contact resistance.

However, the bulk resistance of PC TIMs is relatively high, with a thermal conductivity coefficient (k) of many PC TIMs being limited to approximately 8 W/m·K, owing to the composition of the PC TIM. Accordingly, what is needed is a PC TIM that exhibits both high wettability (e.g., low contact resistance), as well as a higher thermal conductivity coefficient (e.g., low bulk resistance).

Here, it has been surprisingly found that PC TIM comprising a polymeric matrix material, such as a polyolefin-based resin, and including each of a primary (e.g., first) thermally conductive filler with a particle size of approximately 12-20 μm, a secondary (e.g., second) thermally conductive filler with a particle size of approximately 3-8 μm, a tertiary (e.g., third) thermally conductive filler with a particle size of approximately 1-2 μm, and a quaternary (e.g., fourth) thermally conductive filler with a particle size of approximately 0.1 μm to 0.2 μm results in a thermal conductivity coefficient for the PC TIM that is significantly higher than existing PC TIMs, such as high as approximately 12.09 (W/m·K).

### II. Phase Change-Type Thermal Interface Material Composition:

As described above, the present PC TIM material may comprise each of (1) polymeric matrix material, (2) at least four thermally conductive fillers; (3) a phase change wax, (4) an antioxidant; and (5) a coupling agent. Optionally, the PC TIM may comprise a (6) plasticizer.

The at least four thermally conductive fillers may comprise a first thermally conductive filler, a second thermally conductive filler, a third thermally conductive filler, a fourth thermally conductive filler, where each thermally conductive filler comprises particle sizes in descending order (e.g., particle size of first>second>third>fourth). Optionally, the PC TIM may comprise a fifth thermally conductive filler with a particle size similar to the fourth thermally conductive filler.

### (1) Polymeric Matrix Material

The polymeric matrix material (or “polymer matrix material”) may comprise a resin, such as a polyolefin resin. The polyolefin resin may be selected from any one of, or combination of, polyethylene (PE), such as Low-Density Polyethylene (LDPE) and/or High-Density Polyethylene (HDPE), Polypropylene (PP), and/or Ethylene-Propylene Copolymers (EPR). The polyolefin resin may have a molecular weight from about 3000 g/mol, about 3500 g/mol, about 4000 g/mol, or about 4500 g/mol to about 5000 g/mol, about 6000 g/mol, about 6500 g/mol, or about 7000 g/mol, or any range using any two of the foregoing as endpoints, such as 3000 to 7000 g/mol, 3500 to 6500 g/mol, 4000 to 6000 g/mol, or 4500 to 5000 g/mol.

The polymer matrix material may comprise a polymer resin, hydrocarbon rubber compound, or a combination thereof. In one aspect of the disclosure, the polymer matrix is a hydrogenated polyolefin resin. Further exemplary materials include saturated and unsaturated rubber compounds. In some aspects of the present disclosure, saturated rubbers may be less sensitive to thermal oxidation degradation than unsaturated rubber compounds. Exemplary saturated rubber compounds include ethylene-propylene rubbers (EPR, EPDM), polyethylene/butylene, polyethylene-butylene-styrene, polyethylene-propylene-styrene, hydrogenated polyalkyldiene “mono-ols” (such as hydrogenated polybutadiene mono-ol, hydrogenated polypropadiene mono-ol, hydrogenated polypentadiene mono-ol), hydrogenated polyalkyldiene “diols” (such as hydrogenated polybutadiene dial, hydrogenated polypropadiene diol, hydrogenated polypentadiene diol) and hydrogenated polyisoprene, polyolefin elastomer, or any other suitable saturated rubber, or blends thereof. In one aspect of the disclosure, the polymer matrix material is a hydrogenated polybutadiene mono-ol, which may also be referred to as a hydroxyl-terminated ethylene butylene copolymer, specialty mono-ol.

In one exemplary aspect, the polymeric matrix material comprises a silicone rubber, a siloxane rubber, a siloxane copolymer or any other suitable silicone-containing rubber.

The PC TIM composition provided by the present disclosure may comprise a weight percent a polymer matrix material, for example, from about 3.0 wt. %, about 3.5 wt. %, or about 4.0 wt. % to about 4.5 wt. %, about 5.0 wt. %, or about 5.5 wt. % or within any range using any two of the foregoing as endpoints, such as from 3.0 wt. %. to 5.5 wt. %, 3.5 wt. % to 5.0 wt. %, or 4.0 wt. % to 4.5 wt. %, based on the total weight of the PC TIM composition.

The PC TIM composition may comprise a volume percent of a polymer matrix material, for example, from about 10 vol. %, about 11 vol. %, or about 12 vol. % to about 13 vol. %, about 14 vol. %, or about 15 vol. % or within any range using any two of the foregoing as endpoints, such as from 10 vol. %. to 15 vol. %, 11 vol. % to 14 vol. %, or 12 vol. % to 13 vol. %, based on the total volume of the PC TIM composition.

### (2) Thermally Conductive Filler

The PC TIM composition may comprise at least four thermally conductive fillers. In one aspect of the present disclosure, the PC TIM comprises a first thermally conductive filler, a second thermally conductive filler, a third thermally conductive filler, and a fourth thermally conductive filler.

In an additional aspect of the disclosure, the PC TIM comprises a first thermally conductive filler, a second thermally conductive filler, a third thermally conductive filler, a fourth thermally conductive filler, and a fifth thermally conductive filler.

The PC TIM may comprise a total amount of thermally conductive fillers from about 45 wt. %, about 55 wt. %, or about 65 wt. % to about 75 wt. %, about 85 wt. %, or about 95 wt. %, or any range using any two of the foregoing values as endpoints, such as 45 wt. % to 95 wt. %, 55 wt. % to 85 wt. %, or 65 wt. % to 75 wt. %, based on the total weight of the PC TIM. Specific examples of suitable ranges are set forth below in Table A. The numerical ranges set forth in Table A below are understood to be prefaced by “about”.

TABLE A
Thermally Conductive Filler (wt. %) Loading in PC TIM

| From (wt. %) | To (wt. %) |
|---|---|
| 45 | 95 |
| 45 | 90 |
| 45 | 80 |
| 45 | 75 |
| 45 | 70 |
| 45 | 65 |
| 45 | 55 |
| 55 | 95 |
| 55 | 90 |
| 55 | 80 |
| 55 | 75 |
| 55 | 70 |
| 55 | 65 |
| 65 | 95 |
| 65 | 90 |
| 65 | 80 |
| 65 | 75 |
| 65 | 70 |
| 70 | 95 |
| 70 | 90 |
| 70 | 80 |
| 70 | 75 |
| 75 | 95 |
| 75 | 94 |
| 75 | 93 |
| 75 | 92 |
| 75 | 91 |
| 75 | 90 |
| 75 | 89 |
| 75 | 88 |
| 75 | 87 |
| 75 | 86 |
| 75 | 84 |
| 75 | 82 |
| 75 | 80 |
| 80 | 95 |
| 80 | 94 |
| 80 | 93 |
| 80 | 92 |
| 80 | 91 |
| 80 | 90 |
| 80 | 89 |
| 80 | 88 |
| 80 | 87 |
| 80 | 86 |
| 80 | 84 |
| 80 | 82 |
| 82 | 95 |
| 82 | 94 |
| 82 | 93 |
| 82 | 92 |
| 82 | 91 |
| 82 | 90 |
| 82 | 89 |
| 82 | 88 |
| 82 | 87 |
| 82 | 86 |
| 82 | 84 |
| 84 | 95 |
| 84 | 94 |
| 84 | 93 |
| 84 | 92 |
| 84 | 91 |
| 84 | 90 |
| 84 | 89 |
| 84 | 88 |
| 84 | 87 |
| 84 | 86 |
| 86 | 95 |
| 86 | 94 |
| 86 | 93 |
| 86 | 92 |
| 86 | 91 |
| 86 | 90 |
| 86 | 89 |
| 86 | 88 |
| 88 | 95 |
| 88 | 94 |
| 88 | 93 |
| 88 | 92 |
| 88 | 91 |
| 88 | 90 |
| 88 | 89 |
| 89 | 95 |
| 89 | 94 |
| 89 | 93 |
| 89 | 92 |
| 89 | 91 |
| 89 | 90 |
| 90 | 95 |
| 90 | 94 |
| 90 | 93 |
| 90 | 92 |
| 90 | 91 |
| 91 | 95 |
| 91 | 94 |
| 91 | 93 |
| 91 | 92 |
| 92 | 95 |
| 92 | 94 |
| 92 | 93 |
| 93 | 95 |
| 93 | 94 |
| 94 | 95 |

The PC TIM may comprise a total volume of thermally conductive fillers from about 30 vol. %, about 40 vol. %, or about 60 vol. % to about 70 vol. %, about 80 vol. %, or about 86 vol. %, or any range using any two of the foregoing values as endpoints, such as 30 vol. % to 86 vol. %, 40 vol. % to 80 vol. %, or 60 vol. % to 70 vol. %, based on the total volume of the PC TIM. Each individual filler may not exceed 75 vol. % of the total volume of thermally conductive filler in the PC TIM.

### (i) First Thermally Conductive Filler

The first thermally conductive filler may comprise a thermally conductive powder comprising a thermally conductive metal powder, such as aluminum (Al), aluminum nitride (AlN), silver (Ag), copper (Cu), any other suitable high thermally conductive powder, and any combination thereof. For example, the first thermally conductive filler may be an aluminum powder. The first thermally conductive filler may have an average particle size from about 12 μm, about 15 μm, or about 16 μm to about 18 μm, about 20 μm, or about 30 μm, or any range using any two of the foregoing values as endpoints, such as 12 μm to 30 μm, 15 μm to 20 μm, or 16 μm to 18 μm, as based upon an average particle size (D50) as determined by dynamic light scattering ISO 13320-1.

### (ii) Second Thermally Conductive Filler

The second thermally conductive filler may comprise a thermally conductive powder comprising a thermally conductive metal powder, such as aluminum (Al), aluminum nitride (AlN), silver (Ag), copper (Cu), any other suitable high thermally conductive powder, and any combination thereof. For example, the second thermally conductive filler may be an aluminum powder. The second thermally conductive filler may have an average particle size from about 3 μm, about 4 μm, or about 5 μm to about 6 μm, about 8 μm, or about 12 μm, or any range using any two of the foregoing values as endpoints, such as 3 μm to 12 μm, 4 μm to 8 μm, or 5 μm to 6 μm, as based upon an average particle size (D50) as determined by dynamic light scattering ISO 13320-1.

(iii) Third Thermally Conductive Filler

The third thermally conductive filler may comprise a thermally conductive powder comprising a thermally conductive metal powder, such aluminum (Al), aluminum nitride (AlN), silver (Ag), diamond, and any combination thereof. The third thermally conductive filler may have an average particle size from about 1.0 μm, about 1.2 μm, or about 1.4 μm to about 1.6 μm, about 1.8 μm, or about 2.0 μm, or any range using any two of the foregoing values as endpoints, such as 1.0 μm to 2.0 μm, 1.2 μm to 1.8 μm, or 1.4 μm to 1.6 μm, as based upon an average particle size (D50) as determined by dynamic light scattering ISO 13320-1.

### (iv) Fourth Thermally Conductive Filler

The fourth thermally conductive filler may comprise a thermally conductive powder comprising a thermally conductive metal powder, such as aluminum oxide (Al₂O₃), zinc oxide (ZnO), aluminum nitride (AlN), silver (Ag), diamond, and any combination thereof. For example, the fourth thermally conductive filler may be an aluminum oxide powder. The fourth thermally conductive filler may have an average particle size from about 0.03 μm, about 0.05 μm, or about 0.10 μm to about 0.25 μm, about 0.50 μm, or about 1.0 μm, or any range using any two of the foregoing values as endpoints, such as 0.03 μm to 1.0 μm, 0.05 μm to 0.50 μm, or 0.10 μm to 0.25 μm, as based upon an average particle size (D50) as determined by dynamic light scattering ISO 13320-1.

### (v) Fifth Thermally Conductive Filler

The fifth thermally conductive filler may comprise a thermally conductive powder comprising a thermally conductive metal powder, such as aluminum oxide (Al₂O₃), zinc oxide (ZnO), aluminum nitride (AlN), silver (Ag), diamond, and any combination thereof. For example, the fourth thermally conductive filler may be an aluminum oxide powder. The fifth thermally conductive filler may have an average particle size from about 0.03 μm, about 0.05 μm, or about 0.10 μm to about 0.25 μm, about 0.50 μm, or about 1.0 μm, or any range using any two of the foregoing values as endpoints, such as 0.03 μm to 1.0 μm, 0.05 μm to 0.50 μm, or 0.10 μm to 0.25 μm, as based upon an average particle size (D50) as determined by dynamic light scattering ISO 13320-1.

The fifth thermally conductive filler may be the same or different from the fourth thermally conductive filler.

### (3) Phase Change Wax

The PC TIM may comprise one or more phase change waxes (PC waxes). A phase change wax is a wax having a melting point or melting point range at or below the operating temperature of a portion of an electronic device in which the PC TIM is to be used. An exemplary phase change wax may be paraffin wax or polymeric wax. Paraffin waxes are a mixture of solid hydrocarbons having the general formula CₙH₂ₙ₊₂. The paraffin wax or polymeric wax may have a melting points in the range from about 20° C., about 40° C., or about 60° C. to about 70° C., about 80° C., or about 100° C., or any range using any two of the foregoing as endpoints, such as 20° C. to 100° C., 40° C. to 80° C., or 60° C. to 70° C.

Phase change wax may be any paraffin wax, polymer wax, or combination thereof. In one aspect of the disclosure, the phase change wax may comprise olefin wax. The olefin wax may be any one of, or combination of, polyethylene (PE), such as Low-Density Polyethylene (LDPE) and/or High-Density Polyethylene (HDPE), Polypropylene (PP), and/or Ethylene-Propylene Copolymers (EPR). The phase change wax may have a molecular weight from about 500 g/mol, 1000 g/mol, or 1500 g/mol to 2000 g/mol, 2500 g/mol, or 3000 g/mol, or any range using any two of the foregoing values as endpoints, such as 500 to 3000 g/mol, 1000 to 2500 g/mol, or 1500 to 2000 g/mol.

In some aspects of the present disclosure, the amount of phase change wax can be used to adjust the hardness of the PC TIM. For example, in some aspects of the disclosure wherein the loading of the phase change wax is low, the PC TIM composition may be in the form of a soft gel, and in some aspects of the disclosure wherein the loading of the phase change wax is high, the PC TIM composition may be a hard solid.

The PC TIM may comprise a weight percent of the one or more phase change waxes in an amount, for example, from about 0.05 wt. %, about 0.10 wt. %, or about 0.15 wt. % to about 0.20 wt. %, about 0.40 wt. %, or about 0.60 wt. %, or any ranges using any of the foregoing values as endpoints, such as 0.05 wt. % to 0.60 wt. %, 0.10 wt. % to 0.40 wt. %, 0.15 wt. % to 0.60 wt. %, based on the total weight of the PC TIM.

The PC TIM may comprise a volume percent of the one or more phase change waxes in an amount, for example, from about 0.10 vol. %, about 0.50 vol. %, or about 1.00 vol. % to about 1.20 vol. %, about 1.40 vol. %, or about 1.60 vol. %, or any ranges using any of the foregoing values as endpoints, such as 0.10 vol. % to 1.60 vol. %, 0.50 vol. % to 1.40 vol. %, 1.00 vol. % to 1.20 vol. %, based on the total volume of the PC TIM.

### (4) Antioxidant

The PC TIM may comprise at least one antioxidant. The antioxidant may inhibit thermal degradation of the polymer matrix by transferring elections of a free radical to an oxidizing agent. Exemplary antioxidants may include phenolic-type antioxidants, amine-type antioxidants, or any other suitable type of antioxidant or combinations thereof, such as a sterically hindered phenol or amine type antioxidant. Exemplary antioxidants include phenol type antioxidants such as Irganox® 1076, or octadecyl 3-(3,5-di-(tert)-butyl-4-hydroxyphenyl) propionate; amine type antioxidants such as Irganox® 565, or 2,6-di-tert-butyl-4-(4,6-bis(octylthio)-1,3,5-triazin-2-ylamino) phenol, and sulfur containing phenolic antioxidants, such as a sterically hindered sulfur containing phenolic antioxidant. Other exemplary antioxidants may include Irganox® 1010, Irgafox® 168, and Irganox® 802.

The PC TIM may comprise a weight percent of total antioxidant, for example, from about 0.20 wt. %, about 0.25 wt. %, or about 0.30 wt. % to about 0.40 wt. %, about 0.50 wt. %, or about 0.60 wt. %, or any ranges using any of the foregoing values as endpoints, such as 0.20 wt. % to 0.60 wt. %, 0.25 wt. % to 0.50 wt. %, 0.30 wt. % to 0.40 wt. %, based on the total weight of the PC TIM.

The PC TIM may comprise a volume percent of an antioxidant, for example, from about 0.50 vol. %, about 0.80 vol. %, or about 1.00 vol. % to about 1.20 vol. %, about 1.40 vol. %, or about 1.60 vol. %, or any ranges using any of the foregoing values as endpoints, such as 0.50 vol. % to 1.60 vol. %, 0.80 vol. % to 1.40 vol. %, 1.00 vol. % to 1.20 vol. %, based on the total volume of the PC TIM.

### (5) Coupling Agent

The PC TIM may comprise one or more coupling agents. Inclusion of a coupling agent may improve thermal properties, such as properties at relatively high temperatures.

The coupling agent may be selected one or several types from silane coupling agents, titanate coupling agents, aluminate coupling agent, zirconate coupling agent and stearic acid coupling agent.

In one example, the coupling agent is titanium IV 2, 2 (bis 2-propenolatomethyl) butanolato, tris(dioctyl)pyrophosphato-O. Preferred titanate coupling agents include: titanium IV 2,2 (bis 2-propenolatomethyl)butanolato, tris(dioctyl)pyrophosphato-O; zirconium IV 2,2 (bis 2-propenolatomethyl)butanolato, tris(diisooctyl)pyrophosphato-O; titanium IV 2-propanolato, tris(dioctyl)-pyrophosphato-O) adduct with 1 mole of diisooctyl phosphite; titanium IV bis(dioctyl)pyrophosphato-O, oxoethylenediolato, (Adduct), bis(dioctyl) (hydrogen)phosphite-O; titanium IV bis(dioctyl)pyrophosphato-O, ethylenediolato (adduct), bis(dioctyl)hydrogen phosphite; and zirconium IV 2,2-bis(2-propenolatomethyl) butanolato, cyclo di[2,2 (bis 2-propenolatomethyl) butanolato], pyrophosphato-O,O.

The coupling agent may increase the dispersion and wettability of the PC TIM composition.

The PC TIM composition may comprise a weight percent of one or more coupling agents, for example, from about 0.25 wt. %, about 0.30 wt. %, or about 0.40 wt. % to about 0.50 wt. %, about 0.60 wt. %, or about 0.75 wt. % or within any range using any two of the foregoing as endpoints, such as from 0.25 wt. %. to 0.75 wt. %, 0.30 wt. % to 0.60 wt. %, or 0.40 wt. % to 0.50 wt. %, based on the total weight of the PC TIM composition.

The PC TIM composition may comprise a volume percent of one or more coupling agents, for example, from about 0.70 vol. %, about 1.00 vol. %, or about 1.20 vol. % to about 1.40 vol. %, about 1.60 vol. %, or about 2.00 vol. %, or within any range using any two of the foregoing as endpoints, where vol. % is based on the total weight of the PC TIM composition, such as from 0.70 vol. %. to 2.00 vol. %, 1.00 vol. % to 1.60 vol. %, or 1.20 vol. % to 1.40 vol. %, based on the total volume of the PC TIM composition.

### (6) Plasticizer

Optionally, the PC TIM may comprise a plasticizer. A plasticizer is an additive used to lower the viscosity, increase the flexibility, softness, and/or workability of a composition by reducing intermolecular forces and lowering the composition's glass transition temperature (Tg).

A plasticizer may reduce the stiffness of the PC TIM and lower its softening or transition temperature, allowing the PC TIM to flow, wet, and conform more easily to surface asperities when it reaches its phase-change point. Suitable plasticizers may include phthalates, such as diocyl phthalate (DOP) di-2-ethylhexyl phthalate (DEHP), diisononyl phthalate (DINP), and diisodecyl phthalate (DIDP); non-phthalate plasticizers, such as diocyl terephthalate (DOTP), tris(2-ethylhexyl)trimellitate (TOTM), acetyl tributyl citrate (ATBC), triethyl phosphate (TEP), and triphenyl phosphate (TPP); polymeric plasticizers, such as polyesters of adipic, sebacic, or glutaric acids, and polyethylene glycol (PEG); and bio-based plasticizers, such as epoxidized soybean oil (ESBO), and caster oil derivatives.

The PC TIM composition may comprise a weight percent of plasticizer, if present, from about 0.01 wt. %, about 0.30 wt. %, or about 0.40 wt. % to about 0.50 wt. %, about 0.75 wt. %, or about 1.0 wt. % or within any range using any two of the foregoing as endpoints, such as from 0.01 wt. %. to 1.0 wt. %, 0.30 wt. % to 0.75 wt. %, or 0.40 wt. % to 0.50 wt. %, based on the total weight of the PC TIM composition.

### II. Properties of the Phase Change-type Thermal Interface Material

As described previously, exiting PC TIMs may exhibit high wettability performance, but the bulk resistance of existing PC TIM materials limits the overall thermal conductivity.

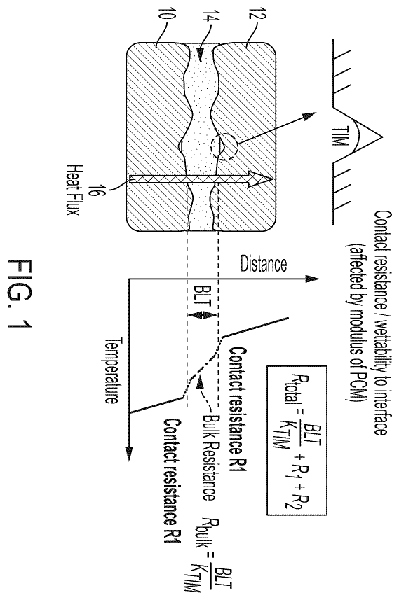

As illustrated in FIG. 1, an electronic component 10, such as a chip, may be adjacent to a heat sink 12. There may be a gap 14 with various spaces or volumes between the surfaces of electronic component 10 and heat sink 12. The PC TIM composition 20 may be inserted into gap 14.

There may be heat flux 16 from the electronic component 10 to a heat sink 12 based upon multiple parameters, including the contact resistance between both electronic component 10 and PC TIM composition 20 and heat sink 12 and PC TIM composition 20 as well as the thermal resistance (Rₜₒₜₐₗ) of PC TIM composition 20 itself, as represented by equation (I) below:

$${R}_{Total} = \frac{BLT}{{K}_{TIM}} + {R}_{1} + {R}_{2} \qquad Equation ( I )$$

where BLT represents the bond layer thickness of the TIM material (m), K_{TIM} represents the thermal conductivity coefficient of the TIM material (W/m·K); R₁ represents the thermal resistance at interface 1 (e.g., the heat source and the TIM material) and R₂ represents the thermal resistance at interface 2 (e.g., the heat sink and the TIM material).

As described previously, PC TIMs exhibit inherently good wettability (e.g., R₁ and R₂ are relatively low). Therefore, in a system where bond layer thickness is held constant (such as at approximately 50 μm) reducing the total thermal resistance increases the thermal performance of the PC TIM. This is possible via increasing the thermal conduction coefficient K TIM.

Is has been surprising found that, through the use of a polymer matrix, such as a relatively high weight polyolefin, and the combination with each of the at least four thermally conductive fillers comprising the different particle sizes described previously, thermal conductivity coefficients (K_{TIM}) from about 8.1 W/m·K, about 8.2 W/m·K, about 8.4 W/m·K, or about 8.8 W/m·K to about 9.0 W/m·K, about 9.2 W/m·K, about 9.4 W/m·K, or about 12.09 W/m·K, are possible, as measured based upon ASTM D5470. This results in a lower thermal resistance of the PC TIM material, and correspondingly higher thermal performance, as compared with traditional PC TIMs.

The PC TIM may have a thermal resistance (Rₜₒₜₐₗ) of less than 0.150° Ccm²/W, less than 0.130° Ccm²/W, less than 0.120° Ccm²/W, less than 0.110° Ccm²/W, or less than 0.100° Ccm²/W, at 50 μm as determined using equation (1).

Thermal impedance (Z) accounts for how temperature varies over time as heat flows through a material. Heat flow (e.g., flux) may change with time and may be represented as a complex impedance in the frequency domain. Moreover, thermal impedance (TI), which is directly related to thermal resistance, is also lower for the present PC TIM materials. The thermal impedance (Z_{TH}) may be calculated using equation (II).

$${Z}_{TH} = \frac{t}{{K}_{TIM} \times A} \qquad Equation ( II )$$

where t is the thickness of the TIM (m), K_{TIM} is thermal conductivity of the TIM (W/m K), and A is the contact area through which heat is transferred (square meters, m²).

To determine thermal impedance, a thermal impedance tester or an equivalent apparatus capable of applying controlled heat and measuring temperature difference across the sample may be used for the measurement. A sample of TIM, such as the PC TIM, may be cut to a 1 inch² circle and placed between the heat source and the cooling end (both test heads are copper coated with nickel) of the thermal impedance tester. The sample should be flat and parallel on both sides to ensure good contact during testing. A force of 35 psi may be applied on the test head to ensure good thermal contact with PC TIM and minimize air gaps. A constant heat load (120 W) may be applied to one side of the test head while monitoring the temperature on both sides with six temperature sensors (three in each head) uniformly distributed along the test head. The steady-state temperature differences between the two sides of the sample may be recorded and used to calculate the thermal impedance. This method is described in ASTM D5470.

Here, the TI value (Z_{TH}) of the PC TIM, assuming a thickness t of 50 μm and a contact area A of 5.06 cm² (a circle with a diameter of 1 inch) may be from 0.069° Ccm²/W, about 0.078/W, or about 0.088° Ccm²/W to about 0.079° Ccm²/W, about 0.088° Ccm²/W, or about 0.98° Ccm²/W, or any range using any two of the foregoing values as endpoints, such as 0.069 to 0.088° Ccm²/W, 0.078 to 0.098° Ccm²/W, or 0.069 to 0.098° Ccm²/W, as determined according to ASTM D5470.

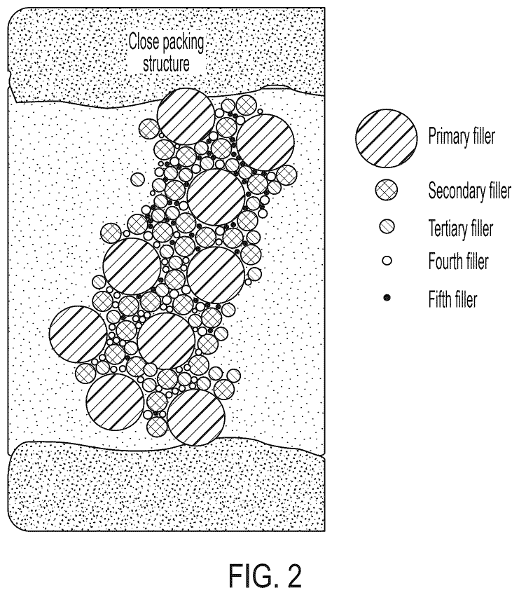

Without being bound by any theory, it is believed that the combination of each of the primary, secondary, tertiary, and quaternary fillers, each comprising the different particle size hierarchy, with the polymeric matrix material results in a close packing structure, and resulting continuous thermal conductivity path, such as illustrated in FIG. 2.

Specifically, a close packing structure of particles creates continuous thermal conduction pathways by increasing contact between the high-conductivity fillers. This reduces thermal resistance and boosts the overall thermal conductivity, as heat flows more easily through the densely packed fillers rather than the lower-conductivity matrix.

In addition to the material's enhanced thermal properties (e.g., lower bulk and total thermal resistance, lower thermal impedance, higher thermal conductivity, etc.) the present TIM also exhibits favorable flowability characteristics, include high pump out resistance. Pump-out resistance of a PC TIM refers to the TIM material's ability to stay in place and not migrate or leak out of the intended thermal interface area during operation, especially under temperature fluctuations and mechanical stresses. High pump-out resistance ensures consistent thermal performance by preventing the TIM from being displaced from the contact surfaces. Complex Modulus (Pa·S) and Tangent delta (Tan δ) may be used to evaluate how a TIM will behave under dynamic conditions. Here, a higher complex modulus and lower Tan δ values typically indicate better pump-out resistance, meaning the TIM will maintain its position and thermal performance over time and under stress.

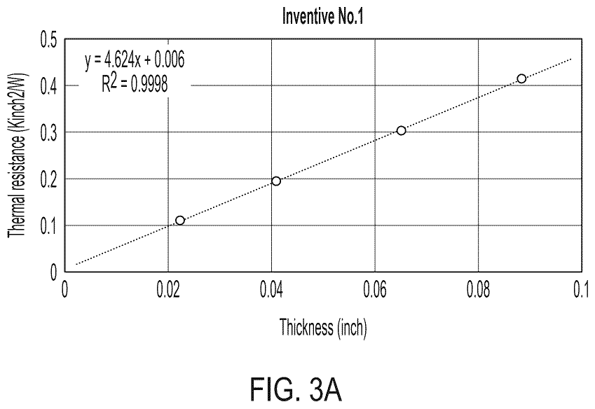

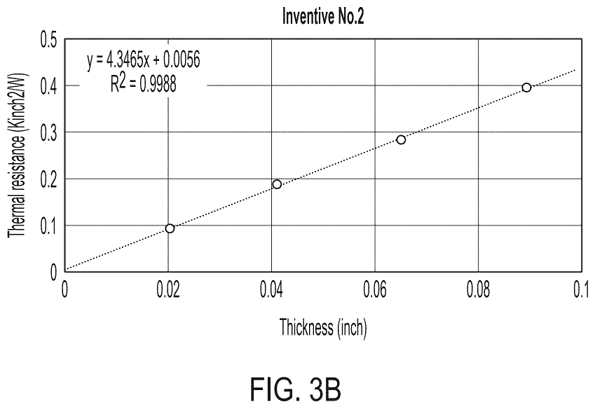

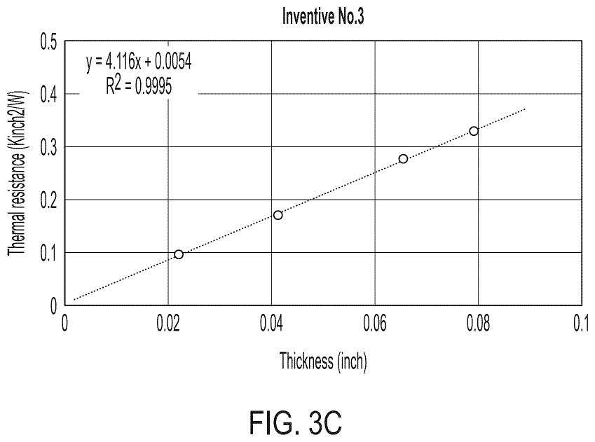

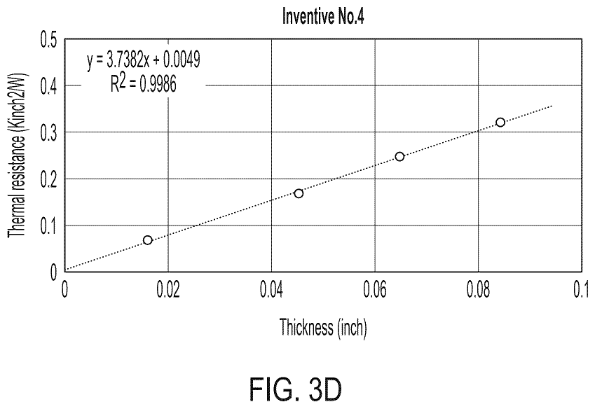

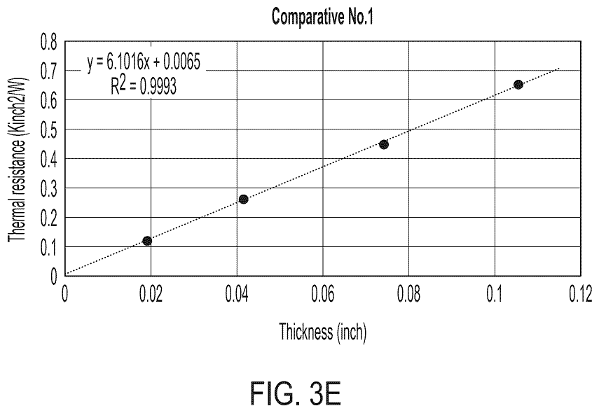

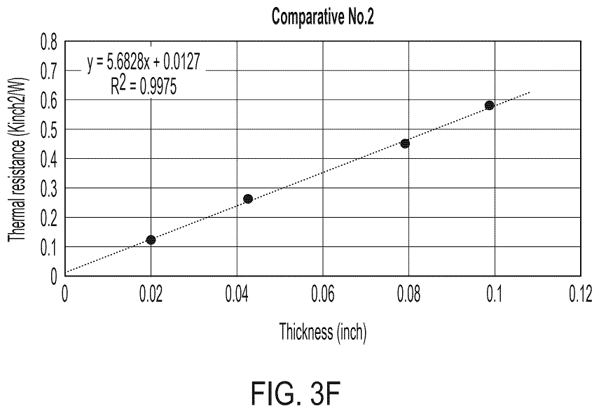

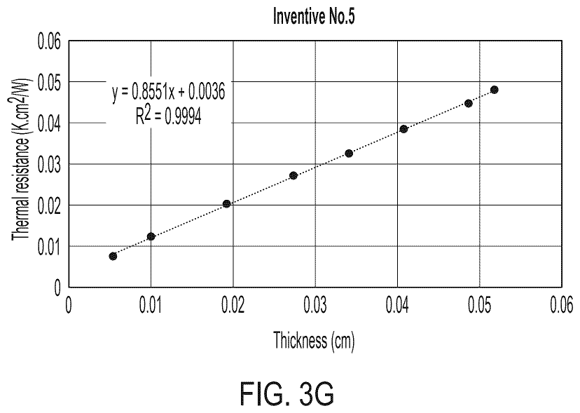

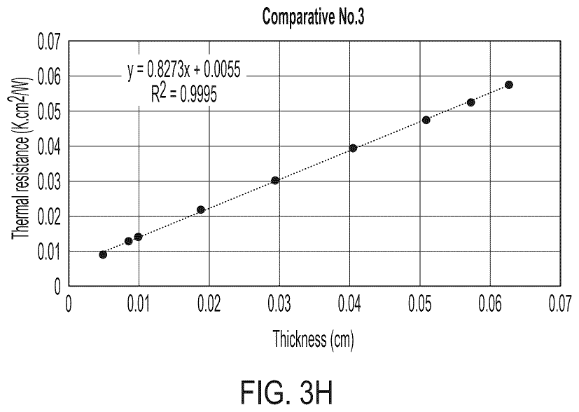

As described in Tables 2-4, and as illustrated in FIGS. 3A-H, 4, and 5, the present PC TIM material outperforms similar PC TIM materials regarding pump-out resistance in view of thermal performance. The complex modulus of the phase change TIMs may be measured using dynamic mechanical analyzer (DMA) with the axial force control model (frequency of 1 HZ, strain of 1%, temperature range from 140° C. to 40° C.). And loss tan angle was calculated using equation (III) below:

$$tan δ = \frac{{M}^{″} ( ω )}{{M}^{′} ( ω )} \qquad Equation ( III )$$

where M″ (ω) represents the loss modulus (viscous component) and M′ (δ) represents the storage modulus (elastic component). The tan δ is equal to the ratio of viscosity to elasticity. A low factor means that the proportion of viscosity component is reduced, and the elasticity of the material is enhanced. Therefore, under external force applied, the material has a stronger ability to resist deformation, which is referred to as the pump-out resistance. The complex modulus and tan δ are shown in Table 3 and Table 4. Specifically, the PC TIM of the present disclosure has a lower thermal resistance, and therefore, higher thermal conductivity; a higher complex modulus, and a lower Tan δ value than the known TIM formulations, such as the comparative examples described in the Examples section.

Further, the PC TIM may have a higher elastic modulus, or “storage modulus,” than known TIMs. Elastic modulus may represent the PC TIM's resistance to deformation under external force, e.g, shear stress. The pump-out usually occurs during the thermal cycling of electronic devices, due to the mismatch of thermal expansion coefficients. Periodic changes in module warpage causes pump-out, especially at high temperatures when the material becomes soft and its resistance to deformation decreases, making pump-out more likely. To improve a material's pump-out resistance, it is desirable for the elastic modulus to be higher and the tan δ to be lower. The relationship between elastic modulus and complex modulus is shown in Equation (III), and the data of elastic modulus for the PC TIM of the present disclosure is listed in Table 5 in Example 2 below.

The PC TIM may have a complex modulus at 60° C. from about 29800 Pa, about 30000 Pa, or about 40000 Pa to about 48000 Pa, about 80000 Pa, or about 90000 Pa, or any range using any two of the foregoing values as endpoints, such as 29800 Pa to 90000 Pa, 30000 Pa to 80000 Pa, or 40000 Pa to 48000 Pa, as determined by ASTM D7271-06 (2020).

The PC TIM may have a complex modulus at 80° C. from about 12000 Pa, about 15000 Pa, or about 20000 Pa to about 22000 Pa, about 35000 Pa, or about 55000 Pa, or any range using any two of the foregoing values as endpoints, such as 12000 Pa to 55000 Pa, 15000 Pa to 35000 Pa, or 20000 Pa to 22000 Pa, as determined by ASTM D7271-06 (2020).

The PC TIM may have a complex modulus at 100° C. from about 7500 Pa, about 8500 Pa, or about 9500 Pa to about 11000 Pa, about 25000 Pa, or about 35000 Pa, or any range using any two of the foregoing values as endpoints, such as 7500 Pa to 35000 Pa, 8500 Pa to 25000 Pa, or 9500 Pa to 11000 Pa, as determined by ASTM D7271-06 (2020).

The PC TIM may have a complex modulus at 120° C. from about 3500 Pa, about 4000 Pa, or about 6000 Pa to about 8000 Pa, about 10000 Pa, or about 12000 Pa, or any range using any two of the foregoing values as endpoints, such as 3500 Pa to 12000 Pa, 4000 Pa to 10000 Pa, or 6000 Pa to 8000 Pa, as determined by ASTM D7271-06 (2020).

The PC TIM may have a complex modulus at 140° C. from about 2000 Pa, about 4000 Pa, or about 6000 Pa to about 8000 Pa, about 10000 Pa, or about 12000 Pa, or any range using any two of the foregoing values as endpoints, such as 3500 Pa to 14000 Pa, 4000 Pa to 10000 Pa, or 6000 Pa to 8000 Pa, as determined by ASTM D7271-06 (2020).

The PC TIM may have a tan δ at 60° C. from about 0.400, about 0.500, or about 0.590 to about 0.600, about 0.650, or about 0.700, or any range using any two of the foregoing values as endpoints, such as 0.400 to 0.700, 0.500 to 0.650, or 0.590 to 0.600, as determined by ASTM D7271-06 (2020).

The PC TIM may have a tan δ at 80° C. from about 0.350, about 0.400, or about 0.450 to about 0.500, about 0.600, or about 0.650, or any range using any two of the foregoing values as endpoints, such as 0.350 to 0.650, 0.400 to 0.600, or 0.450 to 0.500, as determined by ASTM D7271-06 (2020).

The PC TIM may have a tan δ at 100° C. from about 0.300, about 0.400, or about 0.450 to about 0.500, about 0.600, or about 0.650, or any range using any two of the foregoing values as endpoints, such as 0.300 to 0.650, 0.400 to 0.600, or 0.450 to 0.500, as determined by ASTM D7271-06 (2020).

The PC TIM may have a tan δ at 120° C. from about 0.350, about 0.400, or about 0.500 to about 0.550, about 0.600, or about 0.700, or any range using any two of the foregoing values as endpoints, such as 0.350 to 0.700, 0.400 to 0.600, or 0.500 to 0.550, as determined by v.

The PC TIM may have a tan δ at 140° C. from about 0.350, 0.400, or 0.500 to about 0.600, about 0.700, or about 0.800, or any range using any two of the foregoing values as endpoints, such as 0.350 to 0.800, 0.400 to 0.700, or 0.500 to 0.600, as determined by ASTM D7271-06 (2020).

The PC TIM may have an elastic modulus at 60° C. from about 20000, about 30000, or about 40000 to about 60000, about 80000, or about 90000, or any range using any two of the foregoing values as endpoints, such as 20000 to 90000, 30000 to 80000, or 40000 to 60000, as determined by ASTM D7271-06 (2020).

The PC TIM may have an elastic modulus at 80° C. from about 10000, about 15000, or about 20000 to about 30000, about 40000, or about 50000, or any range using any two of the foregoing values as endpoints, such as 10000 to 50000, 15000 to 40000, or 20000 to 30000, as determined by ASTM D7271-06 (2020).

The PC TIM may have an elastic modulus at 100° C. from about 6000, about 6800, or about 9000 to about 10000, about 20000, or about 30000, or any range using any two of the foregoing values as endpoints, such as 6000 to 30000, 6800 to 20000, or 9000 to 10000, as determined by ASTM D7271-06 (2020).

The PC TIM may have an elastic modulus at 120° C. from about 3000, about 3800, or about 6000 to about 8000, about 10000, or about 20000, or any range using any two of the foregoing values as endpoints, such as 3000 to 20000, 3800 to 10000, or 6000 to 8000, as determined by ASTM D7271-06 (2020).

The PC TIM may have an elastic modulus at 140° C. from about 2000, about 3000, or about 4000 to about 6000, about 10000, or about 12000, or any range using any two of the foregoing values as endpoints, such as 2000 to 12000, 3000 to 10000, or 4000 to 6000, as determined by ASTM D7271-06 (2020).

### EXAMPLES

Aspects of the present disclosure are further illustrated by reference to the following examples. It will be apparent to those skilled in the art that many modifications, both to materials, and methods, may be practiced without departing from the scope of the disclosure.

### Example 1: Inventive PC TIM and Comparative TIM Formulations

Inventive (Inv.) PC TIM compositions 1, 2, 3, and 4 and comparative (Comp.) TIM compositions were formulated according to Table 1 below.

Inventive examples are pump-out resist TIMs with higher thermal conductivity. Comparative TIM No. 1 is non-pump-out TIMs, while Comparative TIM No. 2 is pump-out TIMs with low thermal conductivity.

TABLE 1
Inv. PC TIM and Comp. TIM Formulations

| | Inventive | Inventive | Inventive | Inventive | Comparative | Comparative |
|---|---|---|---|---|---|---|
| | No. 1 | No. 2 | No. 3 | No. 4 | No. 1 | No. 2 |
| Components | (wt. %) | (wt. %) | (wt. %) | (wt. %) | (wt. %) | (wt. %) |
| Polymer | 5.22 | 4.83 | 4.06 | 4.93 | 5.48 | 5.15 |
| Matrix | | | | | | |
| Material | | | | | | |
| First Filler | 11.0 | 40.0 | 37.7 | 38.3 | 40.35 | — |
| (12-20 μm) | | | | | | |
| Second Filler | 37.8 | 26.0 | 32.2 | 25.3 | 26.7 | 40.8 |
| (3-8 μm) | | | | | | |
| Third Filler | 24.89 | 8.27 | 11.6 | 8.20 | — | 26.39 |
| (1-2 um) | | | | | | |
| Fourth Filler | 20.2 | 20.0 | 13.7 | 22.5 | 25.84 | 26.2 |
| (0.03 μm to | | | | | | |
| 0.9 μm) | | | | | | |
| Antioxidant | 0.31 | 0.31 | 0.25 | 0.32 | 0.31 | 0.54 |
| Phase | 0.20 | 0.20 | 0.16 | 0.06 | 0.6 | 0.2 |
| Change Wax | | | | | | |
| Coupling | 0.38 | 0.39 | 0.33 | 0.39 | 0.72 | 0.72 |
| Agent | | | | | | |
| Total % | 100 | 100 | 100 | 100 | 100 | 100 |

### Example 2: Inventive PC TIM and Comparative TIM Properties

Inventive (Inv.) PC TIM compositions 1, 2, 3, and 4 and comparative (Comp.) TIM compositions were placed between a heat source (with 120 W load) and a cooling end (with constant temperature 10° C.). Using equation (1), the thermal conductivity coefficient (K_{TIM}), thermal resistance (Rₜₒₜₐₗ), interface contact resistance (R_{c}), were calculated by fitting the data from four different sample thickness ranging from 50 μm to 250 μm. The thermal resistance was calculated at 50 μm and 100 μm. The results are shown in Table 2 and the graphs of FIGS. 3A-F.

TABLE 2
Thermal Conductivity, Thermal Resistance, and Interface
Contact Resistance of Inv. and Comp. TIM

| | | | Rₜₒₜₐₗ @ 50 μm | Rₜₒₜₐₗ @ 100 μm |
|---|---|---|---|---|
| Formulation | K_{TIM} (W/mK) | R_{c} (° C. cm²/W) | (° C. cm²/W) | (° C. cm²/W) |
| Inventive No. 1 | 8.51 | 0.039 | 0.097 | 0.156 |
| Inventive No. 2 | 9.06 | 0.036 | 0.091 | 0.147 |
| Inventive No. 3 | 9.57 | 0.035 | 0.087 | 0.139 |
| Inventive No. 4 | 10.53 | 0.032 | 0.079 | 0.127 |
| Comparative | 6.45 | 0.042 | 0.119 | 0.197 |
| No. 1 | | | | |
| Comparative | 6.93 | 0.042 | 0.114 | 0.186 |
| No. 2 | | | | |

Inv. PC TIMS 1-4 showed better thermal performance, with thermal conductivity between 8~11 W/mK, and the total thermal resistance (@50 μm thickness) between 0.07~0.1° Ccm²/W.

The complex modulus of the Inv. PC TIMs and Comp. TIMs were measured using dynamic mechanical analyzer (DMA) with the axial force control model (frequency of 1 HZ, strain of 1%, temperature range from 140° C. to 40° C.). And loss tan angle was calculated using equation (III).

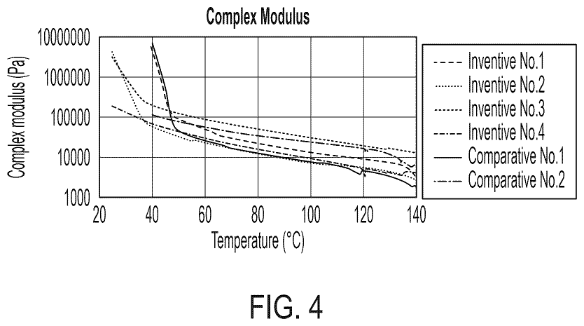

The tan δ is equal to the ratio of viscosity to elasticity. A low factor means that the proportion of viscosity component is reduced, and the elasticity of the material is enhanced. Therefore, under external force applied, the material has a stronger ability to resist deformation, which is the pump-out resistance claimed in present invention. The complex modulus and tan δ were shown in Tables 3 and 4 and illustrated in FIGS. 3 and 4.

TABLE 3
Complex Modulus of Inv. PC TIMs and Comp. TIMs

| | Complex modulus (Pa) | | | | |
|---|---|---|---|---|---|
| Formulation | @60° C. | @80° C. | @100° C. | @120° C. | @140° C. |
| Inventive | 48917.7 | 21505.1 | 13148.7 | 8892.52 | 2642.73 |
| No. 1 | | | | | |
| Inventive | 29816.8 | 12617.7 | 8028.93 | 5306.36 | 2735.93 |
| No. 2 | | | | | |
| Inventive | 88125.4 | 50359.4 | 30606.7 | 19721.4 | 12587.4 |
| No. 3 | | | | | |
| Inventive | 29816.8 | 15625.1 | 9216.24 | 4417.48 | 4255.07 |
| No. 4 | | | | | |
| Compar- | 24835.1 | 12470.7 | 7644.62 | 4615.97 | 1714.81 |
| ative | | | | | |
| No. 1 | | | | | |
| Compar- | 56132.5 | 34136.7 | 23910.1 | 16350.6 | 6513.53 |
| ative | | | | | |
| No. 2 | | | | | |

TABLE 4
Tanδ of Inv. PC TIMs and Comp. TIMs

| | Tan (δ) | | | | |
|---|---|---|---|---|---|
| Formulation | @60° C. | @80° C. | @100° C. | @120° C. | @140° C. |
| Inventive | 0.560 | 0.548 | 0.551 | 0.598 | 0.610 |
| No. 1 | | | | | |
| Inventive | 0.695 | 0.614 | 0.609 | 0.655 | 0.798 |
| No. 2 | | | | | |
| Inventive | 0.487 | 0.425 | 0.387 | 0.371 | 0.371 |
| No. 3 | | | | | |
| Inventive | 0.596 | 0.531 | 0.506 | 0.540 | 0.574 |
| No. 4 | | | | | |
| Compar- | 0.808 | 0.775 | 0.763 | 1.030 | 2.512 |
| ative | | | | | |
| No. 1 | | | | | |
| Compar- | 0.502 | 0.408 | 0.362 | 0.422 | 0.433 |
| ative | | | | | |
| No. 2 | | | | | |

The elastic modulus was determined using Equation (III). Compared to Comp. No. 1, Inv. No. 1-4 have higher elastic modulus, i.e., better pump-out resistance, within the temperature range of 80° C. to 140° C. Furthermore, the inventive PC TIM exhibits superior pump-out resistance within 100° C.-140° C. range. Meanwhile, within the same temperature range, the elastic modulus of Inv. No. 3 is better than that of Comp. No. 2.

TABLE 5
Elastic Modulus of Inv. PC TIMs and Comp. TIMs

| | Elastic modulus (Pa) | | | | |
|---|---|---|---|---|---|
| Formulation | @60° C. | @80° C. | @100° C. | @120° C. | @140° C. |
| Inventive | 42681.0 | 18859.0 | 11516.2 | 7632.00 | 2256.11 |
| No. 1 | | | | | |
| Inventive | 24484.3 | 10752.6 | 6857.37 | 4438.92 | 2138.49 |
| No. 2 | | | | | |
| Inventive | 79229.4 | 46347.3 | 28543.8 | 18489.9 | 11801.4 |
| No. 3 | | | | | |
| Inventive | 25612.8 | 13800.2 | 8223.43 | 3886.96 | 3690.34 |
| No. 4 | | | | | |
| Compar- | 19317.3 | 9857.03 | 6077.56 | 3215.40 | 634.239 |
| ative | | | | | |
| No. 1 | | | | | |
| Compar- | 50166.2 | 31607.2 | 22482.4 | 15064.2 | 5977.25 |
| ative | | | | | |
| No. 2 | | | | | |

### Example 2: Inventive PC TIM Compositions 5 and Comparative PC TIM Composition 3

Inventive (Inv.) PC TIM composition 5 and Comparative (Comp.) PC TIM composition 3 were formulated according to Table 6 below.

TABLE 6
Inv. PC TIM 5-6

| | Comparative | Inventive |
|---|---|---|
| | No. 3 | No. 5 |
| Components | (wt. %) | (wt. %) |
| Polymer | 4.12 | 4.13 |
| Matrix | | |
| Material | | |
| First Filler | 35.93 | 36 |
| (12-30 μm) | | |
| Second Filler | 29.29 | 29.29 |
| (3-12 μm) | | |
| Third Filler | 10.99 | 10.88 |
| (1-2 μm) | | |
| Fourth Filler | 7.33 | 7.33 |
| (0.03 μm to | | |
| 1.0 μm) | | |
| Fifth Filler | 11.34 | 11.25 |
| (0.03 μm to | | |
| 1.0 μm) | | |
| Antioxidant | 0.20 | 0.20 |
| Antioxidant | 0.13 | 0.06 |
| Phase | 0.32 | 0.23 |
| Change Wax | | |
| Coupling | 0.37 | 0.37 |
| Agent | | |
| Plasticizer | 0 | 0.29 |
| Total % | 100 | 100 |

Inventive (Inv.) PC TIM composition 5 and Comp. PC TIM composition 3 were placed between a heat source (with 120 W load) and a cooling end (with constant temperature 10° C.). Using equation (I), the thermal conductivity coefficient (K_{TIM}), thermal resistance (Rₜₒₜₐₗ), interface contact resistance (R_{c}), were calculated by fitting the data from four different sample thickness ranging from 50 μm to 250 μm. The thermal resistance was calculated at 100 μm. The results are shown in Table 7.

TABLE 7
Thermal Conductivity, Thermal Resistance, and
Interface Contact Resistance of Inv. PC TIM
Composition 5 and Comp. PC TIM Composition 3

| | | | Rₜₒₜₐₗ @ 100 μm |
|---|---|---|---|
| Formulation | K_{TIM} (W/mK) | R_{c} (° C. cm²/W) | (° C. cm²/W) |
| Comparative | 12.09 | 0.055 | 0.138 |
| No. 3 | | | |
| Inventive No. 5 | 11.7 | 0.036 | 0.125 |

The complex modulus of the Inv. PC TIM 5 and Comp. PC TIM 3 were measured using dynamic mechanical analyzer (DMA) with the axial force control model (frequency of 1 HZ, strain of 1%, temperature range from 140° C. to 40° C.). And loss tan angle was calculated using equation (III).

The tan δ is equal to the ratio of viscosity to elasticity. A low factor means that the proportion of viscosity component is reduced, and the elasticity of the material is enhanced. Therefore, under external force applied, the material has a stronger ability to resist deformation, which is the pump-out resistance claimed in present invention. The complex modulus and tan δ were shown in Tables 8 and 9.

TABLE 8
Complex Modulus of Inv. PC TIMs 5-6

| | Complex modulus (Pa) | | | | |
|---|---|---|---|---|---|
| Formulation | @60° C. | @80° C. | @100° C. | @120° C. | @140° C. |
| Compar- | 185330 | 102828 | 63880.1 | 43387.6 | 18882.8 |
| ative | | | | | |
| No. 3 | | | | | |
| Inventive | 122215 | 67870.1 | 41263.9 | 26291.6 | 11766.2 |
| No. 5 | | | | | |

TABLE 9
Tanδ of Inv. PC TIMs 5-6

| | Tan (δ) | | | | |
|---|---|---|---|---|---|
| Formulation | @60° C. | @80° C. | @100° C. | @120° C. | @140° C. |
| Compar- | 0.461 | 0.438 | 0.456 | 0.512 | 0.573 |
| ative | | | | | |
| No. 3 | | | | | |
| Inventive | 0.436 | 0.407 | 0.380 | 0.401 | 0.424 |
| No. 5 | | | | | |

The elastic modulus was determined using Equation (III).

TABLE 10
Elastic Modulus of Inv. PC TIMs

| | Elastic modulus (Pa) | | | | |
|---|---|---|---|---|---|
| Formulation | @60° C. | @80° C. | @100° C. | @120° C. | @140° C. |
| Compar- | 168280 | 94182.3 | 58123.1 | 38612.7 | 16386.9 |
| ative | | | | | |
| No. 3 | | | | | |
| Inventive | 112037 | 62869.4 | 38572.3 | 24402.1 | 10832.4 |
| No. 5 | | | | | |

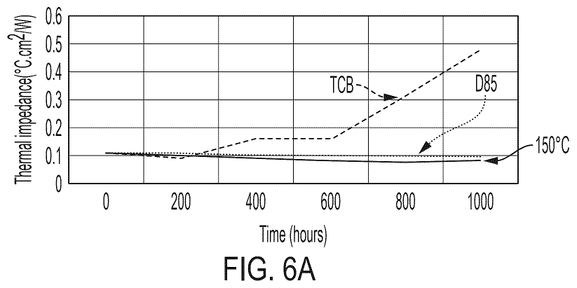

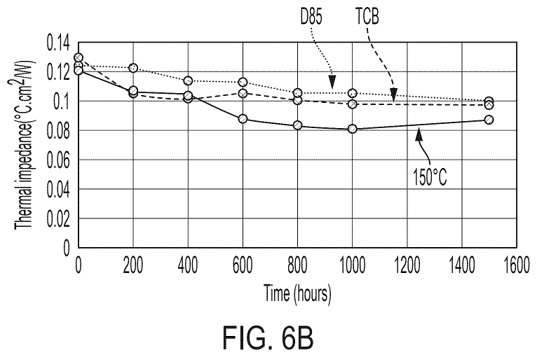

Further, the thermal impedance of Inv. PC TIM composition 5 and Comp. PC TIM composition 3 were calculated. Inv. PC TIM 5 and Comp. PC TIM 3 were each applied and cured to a substrate (sandwich wafer). The Samples were tested in a TCB (−55° C. to 125° C.) test chamber, a D85 (85° C. and 85 relative humidity) test chamber, and a 150° C. test chamber. Each sample was placed into one of the test chambers. After 200 hours, the sandwich samples were taken out and measured thermal impedance using dynamic state method ASTM E1461. The process was repeated every 200 hours for 1500 hours. As shown in the results of FIGS. 6A and 6B, the comparative PC TIM 3 failed the TCB aging test (FIG. 6A) whereas the Inv. PC TIM 5 passed all three 1500 hour aging tests.

Wherein particular examples of this disclosure have been described above for purposes of illustration, it will be evident to those skilled in the art that numerous variations of the details of the present disclosure may be made without departing from the disclosure as defined in the appended claims. This application is therefore intended to cover any variations, uses, or adaptations of the disclosure using its general principles. Further, this application is intended to cover such departures from the present disclosure as come within known or customary practice in the art to which this disclosure pertains and which fall within the limits of the appended claims.

What is claimed is:

1. A phase change thermal interface material, comprising:
a polymeric matrix material;
a first thermally conductive filler with an average particle size between about 12-30 μm;
a second thermally conductive filler with an average particle size between about 3-12 μm;
a third thermally conductive filler with an average particle size between about 1-2 μm; and
a fourth thermally conductive filler with an average particle size between about 0.03-1.0 μm, and
wherein the polymeric matrix material has a thermal conductivity coefficient between 8.1 and 12.09 W/m·K as determined by ASTM D5470.

2. The phase change thermal interface material of claim 1, wherein the polymeric matrix material comprises a polyolefin resin having a molecular weight of between 3000 g/mol to 7000 g/mol.

3. The phase change thermal interface material of claim 1, wherein the first thermally conductive filler comprises aluminum powder.

4. The phase change thermal interface material of claim 1, wherein the phase change thermal interface material comprises 10 wt. % to 45 wt. % of the first thermally conductive filler, based upon the total weight of the phase change thermal interface material.

5. The phase change thermal interface material of claim 1, wherein the second thermally conductive filler comprises aluminum powder.

6. The phase change thermal interface material of claim 5, wherein the phase change thermal interface material comprises 20 wt. % to 40 wt. % of the second thermally conductive filler, based upon the total weight of the phase change thermal interface material.

7. The phase change thermal interface material of claim 1, wherein the third thermally conductive filler comprises at least one of aluminum powder, aluminum nitride powder, silver powder, and diamond powder.

8. The phase change thermal interface material of claim 7, wherein the phase change thermal interface material comprises 5 wt. % to 28 wt. % of the third thermally conductive filler, based upon the total weight of the phase change thermal interface material.

9. The phase change thermal interface material of claim 1, wherein the fourth thermally conductive filler comprises a mixture of zinc oxide and aluminum oxide.

10. The phase change thermal interface material of claim 9, wherein the phase change thermal interface material comprises 10 wt. % to 35 wt. % of the fourth thermally conductive filler, based upon the total weight of the phase change thermal interface material.

11. The phase change thermal interface material of claim 1, further comprising:
a phase change wax;
an antioxidant; and
a coupling agent.

12. The phase change thermal interface material of claim 11, further comprising:
from 0.05 to 0.60 wt. % of the phase change wax;
from 0.20 to 0.60 wt. % of the antioxidant; and
from 0.25 to 0.75 wt. % of the coupling agent, based on the total weight of the phase change thermal interface material.

13. The phase change thermal interface material of claim 1, further comprising a fifth thermally conductive filler with an average particle size between about 0.03-1.0 μm.

14. The phase change thermal interface material of claim 1, further comprising a plasticizer.

15. The phase change thermal interface material of claim 14, further comprising from 0.01 to 1 wt. % of the plasticizer, based on the total weight of the phase change thermal interface material.

16. An electronic component comprising:
a heat sink;
an electronic chip; and
a thermal interface material positioned between the heat sink and the electronic chip, wherein the thermal interface material comprises:
a polymeric matrix material;
a first thermally conductive filler with an average particle size between about 12-30 μm;
a second thermally conductive filler with an average particle size between about 3-12 μm;
a third thermally conductive filler with an average particle size between about 1-2 μm; and
a fourth thermally conductive filler with an average particle size between about 0.03-1.0 μm, and
wherein the polymeric matrix material has a thermal conductivity coefficient between 8.1 and 12.09 W/m·K as determined by ASTM D5470.

17. The electronic component of claim 16, wherein the phase change thermal interface material has an elastic modulus greater than 3800 at 120° C., as determined by ASTM D7271-06 (2020).

18. The electronic component of claim 16, wherein the phase change thermal interface material has Tangent Delta value less than 0.70 at 120° C., as determined by ASTM D7271-06 (2020).

19. The electronic component of claim 16, wherein the thermal interface material further comprises:
from 0.05 to 0.60 wt. % of a phase change wax;
from 0.20 to 0.60 wt. % of an antioxidant; and
from 0.25 to 0.75 wt. % of a coupling agent, based on the total weight of the phase change thermal interface material.

20. The electronic component of claim 16, further comprising:
a fifth thermally conductive filler with an average particle size between about 0.03-1.0 μm; and
from 0.01 to 1 wt. % of a plasticizer, based on the total weight of the phase change thermal interface material.
